(19) United States
(12) Patent Application Publication
(10) Pub. No.: US 2005/0109386 A1
(43) Pub. Date: May 26, 2005

(54) System and method for enhanced thermophotovoltaic generation

(75) Inventor: Robert A. Marshall, Georgetown, TX (US)

Correspondence Address: Robert A. Marshall, 324 Doe Run, Georgetown, TX, 78628, US

(73) Assignee: Practical Technology, Inc.

(21) Appl. No.: 10/984,261

(22) Filed: Nov. 9, 2004

Related U.S. Application Data
(60) Provisional application No. 60/518,488, filed on Nov. 10, 2003.

(51) Int. Cl. H01L 31/00; H01L 35/30

(52) U.S. Cl. 136/253; 136/205

(57) ABSTRACT

A system and method for lower cost, high efficiency, thermophotovoltaic distributed generation includes: an emitter, a photovoltaic cell, and transient electrical energy storage.

### RELATED APPLICATIONS

This application claims the priority benefit of U.S. Provisional Application Ser. No. 60/518,488, entitiled “System and Method for Thermal to Electric Energy Conversion”, filed Nov. 10, 2003.

### TECHNICAL FIELD OF THE INVENTION

This invention relates generally to the field of thermophotovoltaic electric generation and more specifically to a high reliability, high efficiency, distributed generation system.

### BACKGROUND OF THE INVENTION

The field of thermophotovoltaic (TPV) generation suffers for a variety of reasons, including: poor energy conversion efficiency, high installation cost, high generation cost per watt hour, high capital cost, variable load, high peak loads, fuel choice, and low manufacturing volume. These factors severely limit public acceptance.

TPV systems suffer from a poor spectral match between the emitter and the photovoltaic (PV) cells. Emissions with wavelengths below the PV bandgap simply heat the PV and emissions with wavelengths above the bandgap heat the PV, less the bandgap energy. Hotter PV cells result in wasted energy and higher recombination losses within the cell. Thus, selecting emissions just slightly above the PV bandgap will optimize efficiency. US 6,583,350 B1 “Thermophotovoltaic Energy Conversion Using Photonic Bandgap Selective Emitters” utilizes a woodpile 3D photonic band gap (PBG) with a complex dielectric constant emitter material, such as Tungsten, to improve the spectral matching over traditional blackbody, rare earth, or micro structured materials, thereby increasing system efficiency. Lower efficiency wavelengths are still emitted, but at lower power than more common emitters, limited by the photonic crystal structure itself and that the surface disruptions of the crystal form an incomplete band gap at the surface. Woodpile and post/hole PBGs are fabricated with multilayer semiconductor processes.

The emitter in a TPV system frequently has peak emissions in the infrared spectrum. This favors the use of low energy electronic band gap PV cells. While it increases the TPV efficiency, many cells must be connected in series to generate a sufficiently high output voltage for efficient power conversion. Some light is lost in the finite area between series PV cells. Low band gap cells also use less popular semiconductors, have extremely low manufacturing volumes, and are more costly.

PV cells have a high internal impedance. A maximum electrical output power point exists as a function of: optical input power, temperature, cell to cell variance, and age. Allowing a voltage or current greater or lesser than this point will decrease the PV efficiency. If operating near the maximum power point, an increased electric load may attempt to draw power in excess of the maximum power available from the PV, causing the voltage to quickly collapse and completely drop the load. This is especially a problem with loads containing a switched mode power supply, such as many florescent lights, computers, and other electronic equipment. A switch mode power supply can present a negative load impedance, if the supplies input voltage drops, it will draw more current from the input to provide a constant output. Electric motors can draw large startup currents, the motor may fail to start and the motor become damaged. Also, a load step increase may simply overload a PV system operating at maximum efficiency.

Solar TPV systems are similar to TPV systems, but with a solar input instead of a fossil fuel input. For useful emitter temperatures, a high grade solar input is required, such as from a dish concentrator. Diurnal storage is available to compensate for nightly input power loss. The thermal storage mass must be at the focus of the dish, limiting the maximum energy storage to the weight the feed arm can structurally withstand. An input shutter can reduce heat loss at night. An output shutter allows the system to be turned off.

All TPV systems benefit from solid state operation and the associated lack of failure modes of moving parts and from low acoustic noise.

Thus a need has arisen for a thermophotovoltaic electrical generation system and method to overcome the limitations of existing systems.

### SUMMARY OF THE INVENTION

In accordance with the present invention, a system and method for enhanced TPV generation is provided that addresses disadvantages and problems associated with other systems and methods.

A selective emitter is coupled to a PV cell. A thermally stimulated photonic crystal with a PBG is a selective emitter. The photonic crystal has a wide 3D band gap, one material with a complex dielectric constant, and visible emissions. Visible emissions allow use of PV cells with a higher band gap, more mass produced, and lower cost. A filter is interposed between the PV cell and the emitter to limit out of band emissions. The filter is thermally isolated to reduce thermal emissions from the filter and may also have a photonic band gap.

The PV cells have a maximum power point as a function of incident radiation. An iris is interposed between the emitter and PV cells to limit the energy incident on the PV cells to the maximum efficiency point for the given electric load. Applying an electric load beyond the maximum power point will cause the cell voltage to collapse and even less power will be delivered. Some electric energy is stored in an ultracapacitor to support transient events such as load steps, switching power supplies, and motor starts until the iris is adjusted and the system stabilizes. Without the electric energy storage, the system must be backed off of the maximum power point to allow for transient stability, reducing efficiency. The maximum power point is determined by applying a step in incident energy or in electric load, measuring the system response, and adjusting accordingly.

Thermal input may be a fossil fuel, solar, geothermal, waste heat, or any combination of these. A catalytic converter or an afterburner may reduce fossil fueled NOx emissions. A recuperator may increase burner efficiency. Highly concentrated insolation from a parabolic dish collector may be used as is. Lower grade solar heat, geothermal, or waste heat may require a heat pump to increase the temperature to a useful level for a TPV emission, expanding the range of useful energy sources. The heat pump also reduces the re-radiation of collected energy from the solar thermal collector tube. Thermal storage may be implemented. The thermal storage may be sized to compensate for diurnal to seasonal solar variations or batch variations in waste heat. The thermal storage and TPV converter may be placed in an environmentally protected area, thus providing Uninterruptible Power Supply functionality. Thermal energy may be provided for heating. Reflective and vacuum insulation reduce thermal losses. System components may be paralleled or bussed in any combination for increased reliability.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIG. 1 is a diagram demonstrating one method of TPV power conversion in accordance with the present invention;

FIGS. 2A and 2B are diagrams illustrating a TPV system in accordance with the present invention;

FIG. 3 a diagram illustrating spectral usage in accordance with the present invention;

FIG. 4 is a diagram illustrating power flows;

FIG. 5 is a flowchart demonstrating one method of TPV power conversion in accordance with the present invention.

### DETAILED DESCRIPTION OF EMBODIMENTS OF THE INVENTION

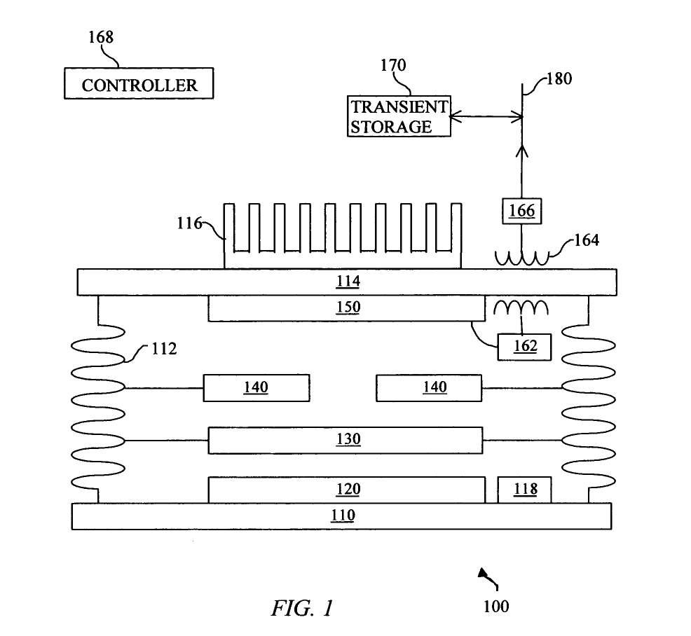

Embodiments of the present invention and their advantages are best understood by referring to FIGS. 1 through 5 of the drawings, in which like numerals refer to like parts.

FIG. 1 is a diagram demonstrating one method of TPV power conversion in accordance with the present invention. A variety of thermal energy sources may deliver heat to emitter 120. Emitter 120 is a photonic crystal possessing a PBG. Preferably emitter 120 consists of: two materials with a large refractive index contrast, a full 3 dimensional PBG, a wide PBG, one material has a complex dielectric constant, and has a low manufacturing cost. All or some of these properties may be present in varying degrees. An inverse opal structure offers a low manufacturing cost, beneficial in market acceptance. Other structures such as a woodpile, or a rod and post, may offer higher performance at a higher cost. A 2 dimensional PBG may be used. In other embodiments Emitter 120 may be a rare earth or a micro structured emitter. Emitter 120 must selectively emit electromagnetic radiation when thermally stimulated. Peak emissions from emitter 120 are spectrally matched to PV cell 150 for optimized efficiency. Preferably emitter 120 has predominant visible emissions, thus allowing a PV cell with higher electronic band gap, thus lower electric currents for an equivalent output power, and thus lower resistive losses in PV 150. However, near infra red emissions can also be tailored to match well known PV cells. Filter 130 improves this match by removing energy below or significantly above the PV 150 bandgap. Filter 130 may be a stacked dielectric filter, a PBG, a phosphor layer, a quantum dot layer, or any other filter. Filtration reduces waste of energy which the PV 150 cannot efficiently convert, associated PV 150 heat dissipation requirements, and lower PV 150 temperatures reduce recombination losses within the PV cell. Losses within filter 130 will heat the filter. Filter 130 is thermally isolated from emitter 120. A portion of filter 130 facing emitter 120 may have a high emissivity, low absorbtivity, coating, preferentially directing this energy back to emitter 120 instead of to PV 150. Filter 130 also limits Physical Vapor Deposition of emitter 120 onto PV 150. In an alternate embodiment, filter 130 may be deposited on emitter 120, easing fabrication requirements, while increasing thermal emissions of filter 130.

PV 150 has a maximum electric power output for a given optical power input. Power limiter 140 is a reflective iris operable to limit incident energy on PV 150 and reflecting unwanted energy back to emitter 120 for re-absorption. The reflective iris is perforated as to maintain approximately even illumination of PV 150 as to not create significant partial shadowing losses. Power limiter 140 is operable to track electric power output 180 to maintain PV 150 at or slightly above the maximum power point. If electric power output 180 requires power beyond the maximum power point of PV 150, the voltage output of PV 150 will collapse. Controller 168 periodically applies a transient to power limiter 140 and monitors the electric output of PV 150 to determine how close PV 150 is operating to its maximum power point and to optimize the steady state condition of power limiter 140. In an alternate embodiment, a load pulse is applied, via transient storage 170 or via a load resistor. Transient storage 170 may first source power then sink power, providing a power transient on PV cells 150 of twice the peak flow from transient storage 170. Alternatively, a single sided pulse may be used.

Voltage collapse can be exacerbated if electric power output 180 is connected to a switching power supply, as a switching power supply will drop its input impedance in attempt to deliver its expected output, causing further voltage collapse of PV 150. Electric motors frequently require a high starting current followed by a lower running current. Failure to provide adequate starting current can cause premature motor failure. Traditionally, a PV cell without significant design margin is not suitable to start a motor due to the PV cell's high impedance. Traditionally, a TPV device must have excess incident energy to have a low enough impedance to allow a motor start, at the expense of efficiency. Load steps at electric power output 180 may also cause voltage collapse if PV 150 is operated close to its maximum power point. Transient storage 170 is an array of ultracapacitors coupled to a bi-directional power supply to provide a low impedance at electric output 180 while operating at the maximum power point of PV 150 and thus mitigate user concerns over motor starts, load steps, switch mode power supplies, and tuning pulses from controller 168. In an alternate embodiment, transient storage may be a capacitor, a battery, or a flywheel.

Emitter 120 is generally operated at a high temperature, between 500K and 1500K. Values beyond this range can be used, but are less desirable. Thermal conduction and convection through air from emitter 120 can be a significant heat loss causing PV 150 to operate at higher temperatures. Hot plate 110, cold plate 114, and bellows 112 form a vacuum can, significantly limiting non-radiative energy coupling. Bellows 112 provides a long thermal path between hot plate 110 and cold plate 114 and allows for relief of thermal stresses. Hot plate 110 and cold plate 114 may be ceramic, metal, or glass. Alternatively, the system may be rearranged to operate within a tank, reducing mechanical stresses from vacuum pressures. Optional getter 118 helps reduce vacuum degradation with time. Optionally, if emitter 120 contains Tungsten, the vacuum may be backfilled with a halogen gas, well known to reduce metal deposition on cold surfaces. Alternatively, after providing appropriate component spacing, backfilling the vacuum with a high Knudsen number gas reduces the mechanical stresses on the vacuum can. Heat sink 116 provides a cooling mechanism of PV 150.

Typical voltages and currents from PV 150 must be converted to levels useful for electric power output 180. A wide input range power supply consists of: primary side switches 162, transformer 164, and secondary side switches 166. Primary side switches 162 and one half of transformer 164 are placed within the vacuum can. Energy is magnetically coupled through non-metallic cold plate 114. No feed through penetrations of the vacuum can are required, improving the long term leak rate of the can. In an alternate embodiment, an electric vacuum feed through is utilized and all of the power conversion is done outside of the vacuum can. If 60 Hz single phase AC source is desired at electric power output 180, power limiter 140 may provide modulation. Power limiter 140 may also include an optical chopper wheel in addition to an iris. Modulating the optical power incident on PV 150 allows smaller bulk capacitors, as ripple currents may be reduced and the energy associated with less than peak voltage output does not need to be electrically stored to maintain the higher efficiency associated with operation at the maximum power point. If a PV cell 150 fails and only a single PV cell 150 is present in TPV power conversion system 100, power limiter 140 is completely closed to minimize lost efficiency. If multiple PV cells 150 are present, a relay or FET may short the underperforming cell. Alternatively, a diode may be substituted for a relay at the expense of higher losses.

TPV power conversion system 100 may be paralleled for increased capacity or increased redundancy. Emitter 120, filter 130, may be segmented for manufacturability. PV 150 may be segmented and series or parallel stacked for increased output voltage or for use of standard size cells. TPV power conversion system may be sized for outputs of anywhere from sub milliwatt to parallel combinations of multiple megawatts.

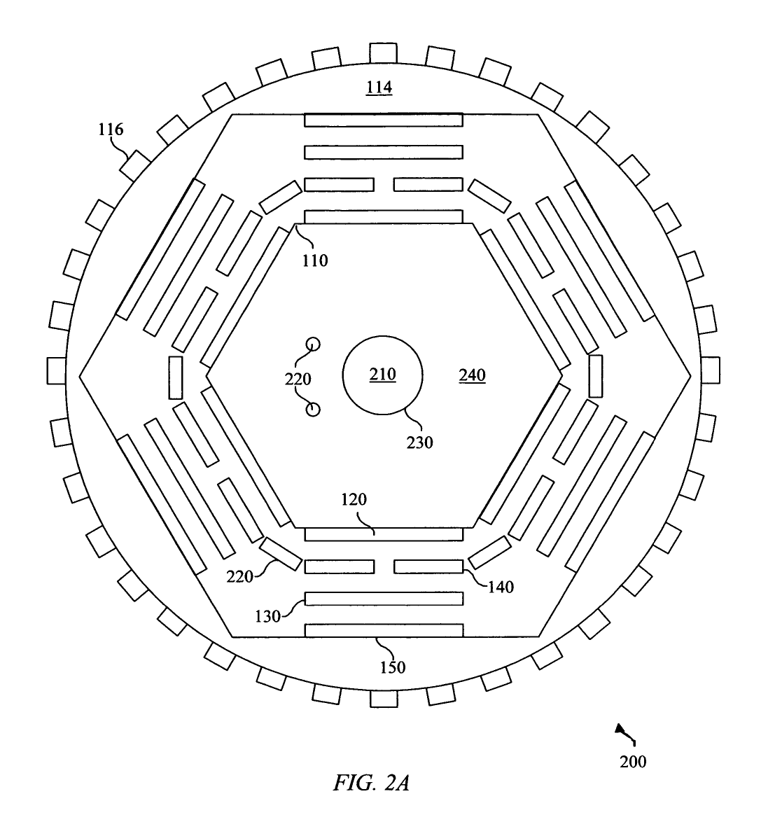

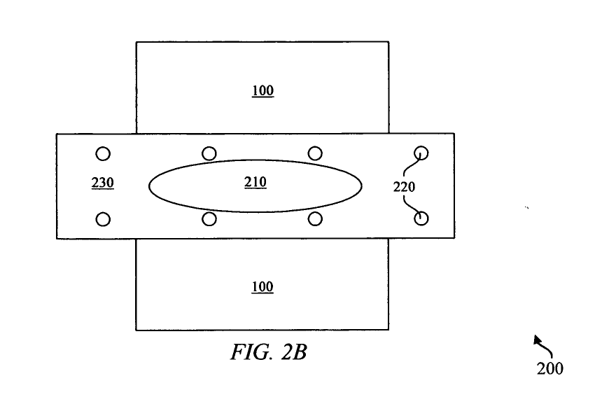

FIGS. 2A and 2B are diagrams illustrating a TPV system 200. Hot gasses 210 heat burner tube 230, which is closely coupled to TPV power conversion system 100 in FIG. 2B and to thermal storage mass 240 in FIG. 2A. Baffles or fins in burner tube 230 increase thermal transfer. A multi fuel fossil fuel burner may generate hot gasses from fuels such as: diesel, fuel oil, kerosene, propane, coal, or gasoline. A variety of vegetable oil, biodiesel, alcohol fuels or other alternative fuels may also be burned. A catalytic converter or an afterburner may decrease NOx emissions. Recuperation may increase burner efficiency. Alternatively, hot gasses may be generated as a waste product of an internal combustion engine or a turbine. Thermal storage mass 240 allows for variable energy fuels containing water, biological growth, cross linking, or fractionalization to be burned. If the heat source does not have high enough temperature for efficient TPV generation, a self-powered, solid-state heat pump, further described and incorporated by reference, is disclosed in U.S. Ser. No. 10/937,831 “Directional Heat Exchanger”. Alternate embodiments may couple TPV power conversion system 100 to any heat source in any useful arrangement. In yet another embodiment, a fuel may be catalytically combusted. The catalytic combustion chamber may have a very low thermal mass, coupled to the low thermal mass of emitter 120, allows for fast thermal response. Optional input or output ports 220 allow for waste heat input, Combined Heat and Power or Combined Cooling Heat and Power. Also, TPV power conversion system 100 may be integrated into a solar heated, hybrid solar, or waste process heat heated as described in application Ser. No. 10/ (filed on the same date as this application) “System and Method For Thermal to Electric Energy Conversion” and is hereby incorporated by reference. Parabolic trough collectors collect insolation and convert it to heat, a self-powered solid-state heat pump elevates the temperature, thermal energy is stored to compensate for diurnal to seasonal variations, and a TPV generator is heated.

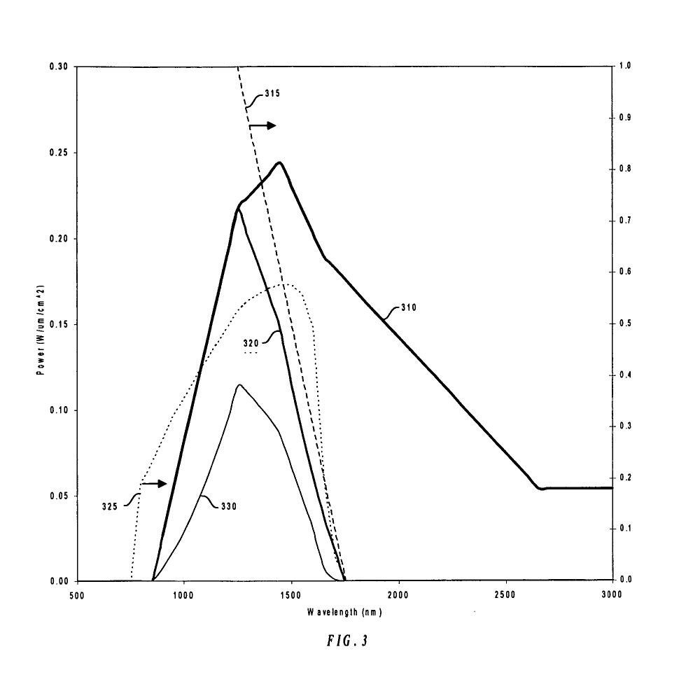

FIG. 3 is a diagram illustrating spectral usage. Example emission spectra of emitter 120, for an 8 layer Tungsten woodpile photonic crystal at 1190K, is shown as emission spectra 310. Filter response 315 of filter 130 is shown for a high pass dielectric filter. Incident power 320 of PV cell 150 is shown. External quantum efficiency 325 of an InGaAs PV cell is shown. Electric output power 330 vs wavelength is shown. For this example, 11.6 W/cm\hat{ }2 is emitted from the PBG, this is filtered to 3.7 W/cm\hat{ }2, and converted to 1.81 W/cm\hat{ }2 allowing for filter losses and external quantum efficiencies. A system efficiency of about 37% is realized. Other spectra are readily envisioned based on Si or GaAs PV cells and for inverse opal structures. Specifically, the emitter and PV are selected for maximum spectral match and a filter is selected to reject out of band energy.

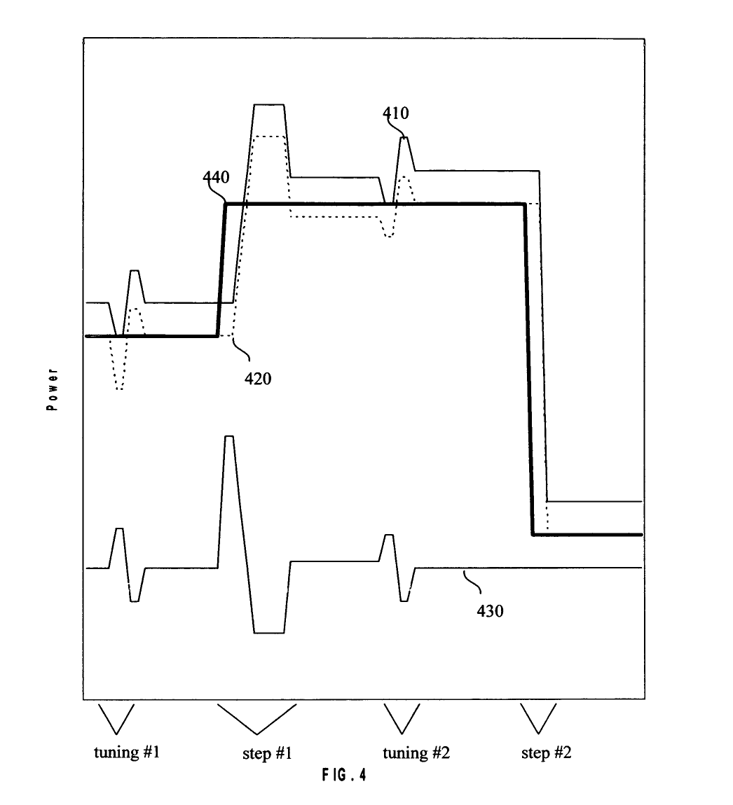

FIG. 4 is a diagram illustrating power flows. PV incident power 410 indicates the optical power incident on PV cell 150, PV output power 420 indicates the electric output power from PV cell 150, transient storage power 430 indicates power flows from transient storage 170, and system output power 440 indicates electric output 180. The relative scale is modified for illustrative purposes.

Initially, the system is shown operating at maximum power, with a minimum energy loss between PV incident power 410 and PV output power 420. A first tuning pulse is illustrated in PV incident power 410. For the negative portion of the pulse, PV cells 150 cannot produce enough energy to supply the load on PV cells 150 and PV output power 420 drops by significantly more than the drop in PV incident power 410. For the positive portion of the pulse, PV cells 150 produce more energy than can be delivered to the given load. The ratio of input to output power of PV cells 150 is measured. From the slope of measured efficiency, it is determined that the PV cells were already operating at the maximum power point for the given load. Two or more power measurements are taken to make this determination. This tuning provides closed loop efficiency optimization. Transient storage 170 delivers or consumes the excess power shown in transient storage power 430 so that system output power 440 does not become unstable with a switch mode power supply load, and has no transient.

The load is increased at a first load step. Stored energy is supplied from transient storage 170 until the incident power 410 is increased to supply the new system output power 440 plus additional power to recharge transient storage 170. Once transient storage 170 is recharged, incident power 410 is returned to a nominal value. The value of desired incident power 410 may be determined, open loop, from a look up table given the desired PV output power 420. The desired PV output power 420 is the system load 440 plus, if the PV cells are not overloaded, power to return to or maintain transient storage 170 in a fully charged state. The lookup table values are not always accurate due to temperature, component aging, dirt or deposits on PV cells 150 or filter 130, inaccurate opening of iris 140, or manufacturing variance in any of these components. Thus, a slight deficiency in output power is shown after the load step, and is supplied from transient storage power 430. Net power flows may be monitored to determine this deficiency and a second tuning pulse applied to determine if incident power 410 should be increased or decreased to re-optimize efficiency. The look up table is updated with the optimized incident energy 410, closing the open loop, replacing default values with learned values. If TPV power conversion system 100 is connected to a load management system, a load may request a change in supplied power before presenting the demand. In this case, incident energy 410 may be adjusted preemptively, thereby reducing transient storage power 430. Again, transient storage 170 delivers the energy deficit or stores the excess energy so that system output power 440 has no transient.

The load is decreased at a second load step. Transient storage 170 is maintained at capacity. The excess power produced by PV cells 150 cannot be consumed and represents a temporary efficiency loss. Iris 140 is adjusted to reduce incident power 410 and regain efficiency.

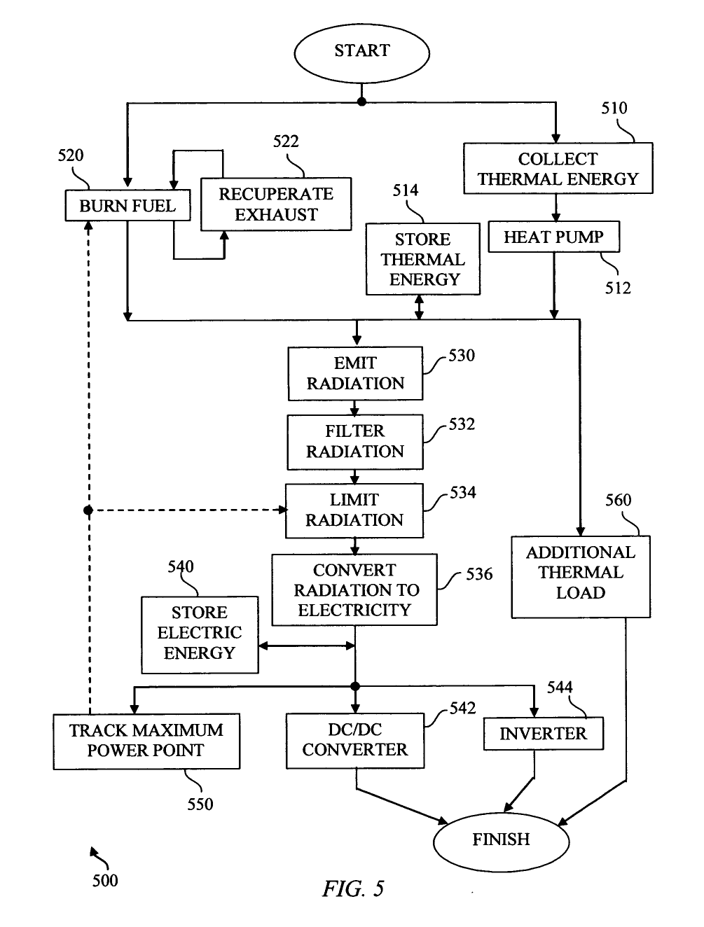

FIG. 5 is a flowchart demonstrating one method of TPV power conversion in accordance with the present invention. A fossil fuel, vegetable oil, or other alternative fuel is burned in step 520. Optionally, exhaust heat may be recuperated or used in a CCHP application in step 522. Other waste thermal sources or a solar thermal source may be utilized in addition or instead of fossil fuels in step 510. If the temperature of waste heat is too low, heat pump 512 may elevate the temperature. Preferably, heat pump 512 is self-powered and solid-state, as to not negatively impact efficiency or reliability, and is further disclosed in U.S. Ser. No. 10/937,831 “Directional Heat Exchanger”. If the heat flow varies with time, as with batch waste heat or solar heat, inhomogeneous fuel, or an uninterruptible source is required, thermal energy is stored in step 514. Storage may be sized to supply energy for seasonal solar variations, diurnal solar variations, batch variations, or for seconds. The heat source may directly support a thermal load in step 560.

Thermal energy is converted to optical energy in step 530. Step 530 employs a photonic crystal emitter with some or all of the following properties: a high refractive index contrast, one material has a complex dielectric constant, a full 3D PBG, a wide band gap, and inverse opal structure. In alternate embodiments, these parameters may vary in degree or be absent. In yet another embodiment, a micro structured, rare earth, or blackbody emitter is employed. Optical emissions are spectrally matched to PV cells in step 532 to maximize PV conversion efficiency. The spectral matching may be accomplished with a dielectric filter, a PBG filter, a phosphor layer, a quantum dot layer, or other optical filter. Optionally, the filter may have a high emissivity coating on a portion of the filter to re-direct dissipated thermal energy back to be re-emitted in step 530. Emitted power is optimized to the maximum power point of the PV cells in step 534. A reflective iris may be used to limit power. PV cells convert spectrally shaped radiation to electricity in step 536. Electricity is stored in step 540 to compensate for: transients, load steps, switch mode power supplies, and optimization of incident radiation by tracking the maximum power point of PV cells in step 550, thereby increasing efficiency. Electricity may be stored in series or parallel combinations of ultracapacitors, capacitors, or batteries. A bidirectional switch mode power supply also in step 540 is operable to maintain output voltage regulation and ultracapacitor charge. Step 550 applies an impulse in the power incident on the PV cells while measuring the slope of the change in input to output power of the PV cells. If the iris is slightly closed and the PV conversion efficiency increases, the incident energy may be decreased. If the iris is slightly closed and the PV conversion decreases, the PV is already operating at the maximum power point and the iris is immediately returned to the original opening, the reduction in incident energy having resulted in operation past the maximum power point and a small collapse in output power. Alternatively or additionally, step 550 may use a lookup table to determine the desired incident power based on the load. The lookup table may be updated with optimized values. Alternatively, step 550 may use bidirectional power supply to create a load step by decreasing and increasing the state of charge of ultracapacitors. Step 550 may also control the burn rate of the heat source. Step 542 provides a DC electric output and step 544 provides an AC electric output. Steps 540, 542, and 544 may be combined to optimize power conversion electronics.

Any step may be combined with itself in a parallel fashion, or any group of steps may be combined in a series or parallel fashion to achieve the desired power flows or desired reliability.

Although embodiments of the system and method of the present invention have been illustrated in the accompanying drawings and described in the foregoing detailed description, it will be understood that the invention is not limited to the embodiment disclosed, but is capable of numerous rearrangements, modifications, and substitutions without departing from the spirit of the invention as set forth and defined by the following claims.

1. A system for thermoelectric power generation comprising:
a heated emitter;
a filter;
a photovoltaic cell;
an input thermal energy regulator; and
transient electric energy storage.

2. The system of claim 1, where said heated emitter is a photonic crystal.

3. The system of claim 2, where said photonic crystal possesses a 3D photonic bandgap.

4. The system of claim 2, where the emission wavelengths are predominantly visible.

5. The system of claim 2, where said photonic crystal possesses an inverse opal structure.

6. The system of claim 2, where said photonic crystal is comprised of one material with a complex dielectric constant.

7. The system of claim 2, where said photonic crystal contains: W, Mo, Cu, Au, Ag, Ge, Ge/Ni, Ge/W, or Ge/Ni/W.

8. The system of claim 2, where the spectra of said emitted energy is tailored to a Si or GaAs photovoltaic cell.

9. The system of claim 2, where said transient energy storage includes a capacitor or ultracapacitor.

10. The system of claim 2, where said filter is one of: a photonic crystal layer with a different photonic bandgap than the photonic bandgap of said emitter, attached to said emitter; a photonic crystal with a different photonic bandgap than the photonic bandgap of said emitter, thermally isolated from said emitter; quantum dot; or phosphor.

11. The system of claim 2, where said input thermal energy regulator consists of: an iris is interposed between said emitter and said photovoltaic cell; and/or a variable input fuel flow control valve.

12. The system of claim 11, where said iris is perforated such to maintain an approximately uniform optical density.

13. The system of claim 11, where said iris is momentarily opened or closed, the resultant change in photovoltaic output is monitored, and input thermal energy is adjusted to operate closer to the maximum power point of said photovoltaic cell.

14. The system of claim 11, where said iris is adjusted by a load manager in anticipation of a load step.

15. The system of claim 2, where a heat source is one or more of: solar, natural gas, propane, kerosene, diesel, coal, animal or vegetable oil, alcohol, geothermal, biologically contaminated fuel, cross linked fuel, fractionated fuel, water contaminated fuel, or waste process heat.

16. The system of claim 15, where a burner also includes a recuperator and/or CCHP ports.

17. The system of claim 15, where insolation is collected and converted to heat with a parabolic trough collector.

18. The system of claim 15, where the temperature of said heat source is elevated with a heat pump.

19. The system of claim 18, where said heat pump includes a photonic band gap emitter.

20. The system of claim 15, where heat is stored for seasonal variations.

21. The system of claim 2, where any block, group of blocks, input or output in the system is duplicated and connected for redundancy.

22. The system of claim 21, where said system is in an environmentally hardened location, excluding a heat source.

23. A means for thermophotovoltaic power conversion comprising:
a thermal input means;
a thermally stimulated photonic crystal optical emitter;
a photovoltaic cell; and
a means for providing a low impedance electric output.

24. The system of claim 23, where said emitter comprises a photonic crystal with a 3D photonic band gap.

25. The system of claim 24, where one material possesses a complex dielectric constant.

26. The system of claim 24, where said photonic crystal has an inverse opal structure.

27. The system of claim 23, where said means of providing a low impedance electric output includes an ultracapacitor.

28. The system of claim 23, where a filter means improves the spectral matching of said emitter to said photovoltaic cell.

29. The system of claim 23, including a means to vary the intensity of the incident energy on the photovoltaic cell such that said photovoltaic cell is operating at its maximum power point.

30. The system of claim 29, including a means to determine said maximum power point by momentarily reducing and/or increasing the incident energy intensity on said photovoltaic cell and monitoring the resultant change in efficiency of said photovoltaic cell while said means for providing a low impedance system electric output prevents any deviation in system electric output.

31. The system of claim 29, including a means to determine said maximum power point by momentarily reducing and/or increasing electric load on said photovoltaic cell and monitoring the resultant change in efficiency of said photovoltaic cell while said means for providing a low impedance system electric output prevents any deviation in system electric output.

32. The system of claim 29, including a lookup table to determine said maximum power point.

33. The system of claim 32, including a learning means to update said lookup table with more accurate values.

34. The system of claim 23, where the means of thermal input includes a burner, catalytic converter, and/or recuperator.

35. The system of claim 23, where the thermal input means includes waste heat generated by another process.

36. The system of claim 23, where the means of thermal input includes a parabolic trough solar concentrator.

37. The system of claim 23, including a means to store collected energy as heat.

38. The system of claim 23, where the temperature of the thermal input is increased with a heat pump.

39. A method of thermophotovoltaic power conversion including:
applying thermal energy;
thermally stimulating a photonic crystal to emit optical radiation;
converting said optical radiation to electric energy utilizing a photovoltaic cell;
adjusting incident energy on said photovoltaic cell for optimum efficiency; and
providing a low impedance output.

40. The method of claim 39, where said photonic crystal exhibits a full 3D photonic bandgap.

41. The method of claim 40, where said photonic crystal has a Lincoln log structure.

42. The method of claim 39, where said photonic crystal contains one material with a complex dielectric constant.

43. The method of claim 39, where said photonic crystal has dominant visible emissions.

44. The method of claim 39, including further spectral shaping to match the optical spectra of said optical radiation to the highest photovoltaic conversion efficiency.

45. The method of claim 39, where the incident energy on said photovoltaic cell is adjusted to the maximum power point of said photovoltaic cell.

46. The method of claim 45, utilizing an iris.

47. The method of claim 39, where the input to output power ratio of said photovoltaic cell is measured, a transient shift in input power is applied, the input to output power ratio is measured again, and the input power is adjusted to increase the input to output power ratio.

48. The method of claim 39, where a capacitor provides said low impedance output.

49. The method of claim 39, where said thermal energy is from a solar and/or fossil fuel and/or bio fuel and/or waste process heat source.
